(19) United States
(12) Patent Application Publication
(10) Pub. No.: US 2010/0289935 A1
(43) Pub. Date: Nov. 18, 2010

(54) IMAGE SENSOR

(75) Inventor: Toshikazu Ohno, Mizuho-shi (JP)

Correspondence Address: DITTHAVONG MORI & STEINER, P.C., 918 Prince Street, Alexandria, VA, 22314, US

(73) Assignee: Sanyo ELectric Co., Ltd., Moriguchi-shi (JP)

(21) Appl. No.: 12/723,126

(22) Filed: Mar. 12, 2010

(30) Foreign Application Priority Data
May 15, 2009 (JP) 2009-118469

(51) Int. Cl. H04N 5/335; H01L 31/14

(52) U.S. Cl. 348/306; 257/225; 257/E31.097; 348/E05.091

(57) ABSTRACT

An image sensor according to the present invention includes a charge forming portion forming charges by photoelectric conversion and a charge transfer region including a charge increasing region for increasing the amount of charges. The image sensor is so formed as to increase dark current generated in at least part of the charge forming portion and the charge transfer region in the charge increasing region for calculating an increasing ratio for the charges on the basis of an output value resulting from a charge signal of the increased dark current.

### CROSS-REFERENCE TO RELATED APPLICATION

The priority application number JP2009-118469, Image Sensor, May 15, 2009, Toshikazu Ohno, upon which this patent application is based is hereby incorporated by reference.

### BACKGROUND OF THE INVENTION

1. Field of the Invention

The present invention relates to an image sensor, and more particularly, it relates to an image sensor including a charge increasing region for increasing the amount of charges.

2. Description of the Background Art

An image sensor including a charge multiplying portion (charge increasing region) for multiplying (increasing) a charge signal with a prescribed multiplication frequency is known in general. The charge multiplying portion of such an image sensor is provided with a plurality of charge multiplying cells for multiplying the charge signal. The charge signal is so input in the charge multiplying cells that the same is multiplied with the prescribed multiplication frequency, and an output value of the multiplied charge signal is acquired. The multiplication factor for the multiplied charge signal is calculated on the basis of the acquired output value. More specifically, an output value in a case of not multiplying the charge signal is first acquired. Then, an output value in a case of multiplying the charge signal with the prescribed multiplication frequency is acquired. The multiplication factor for the multiplied charge signal is calculated by calculating the ratio between the output in the case of not multiplying the charge signal and that in the case of multiplying the charge signal.

In the aforementioned image sensor, however, the multiplication factor is calculated through the ratio between the output value in the case of not multiplying the charge signal and that in the case of multiplying the charge signal with the prescribed multiplication frequency, and hence it is disadvantageously difficult to calculate a multiplication factor (increasing ratio) for a charge signal multiplied with an arbitrary multiplication frequency (increasing frequency).

### SUMMARY OF THE INVENTION

An image sensor according to a first aspect of the present invention includes a charge forming portion forming charges by photoelectric conversion and a charge transfer region including a charge increasing region for increasing the amount of charges, for increasing dark current generated in at least part of the charge forming portion and the charge transfer region in the charge increasing region and calculating an increasing ratio for the charges on the basis of an output value resulting from a charge signal of the increased dark current.

A CMOS image sensor according to a second aspect of the present invention includes a charge forming portion forming charges by photoelectric conversion and a charge transfer region including a charge increasing region for increasing the amount of charges, while the charge increasing region is provided every pixel, for increasing dark current generated in at least part of the charge forming portion and the charge transfer region in the charge increasing region and calculating an increasing ratio for the charges on the basis of an output value resulting from a charge signal of the increased dark current.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view showing the overall structure of a CMOS image sensor according to a first embodiment of the present invention;

FIG. 2 is a sectional view taken along the line 200-200 in FIG. 1;

FIG. 3 is a sectional view taken along the line 300-300 in FIG. 1;

FIG. 4 is a circuit diagram showing the circuit structure of the CMOS image sensor according to the first embodiment of the present invention;

FIG. 5 is a potential diagram for illustrating an operation of transferring dark current (charge signal) in the CMOS image sensor according to the first embodiment of the present invention;

FIG. 6 is a potential diagram for illustrating an operation of multiplying the dark current (charge signal) in the CMOS image sensor according to the first embodiment of the present invention;

FIG. 7 is a schematic diagram for illustrating multiplication frequencies for the dark current (charge signal) in the CMOS image sensor according to the first embodiment of the present invention; and

FIG. 8 is a schematic diagram for illustrating a case of measuring multiplication factors during an imaging operation of a CMOS image sensor according to a fourth embodiment of the present invention.

### DESCRIPTION OF THE PREFERRED EMBODIMENTS

Embodiments of the present invention are now described with reference to the drawings.

### First Embodiment

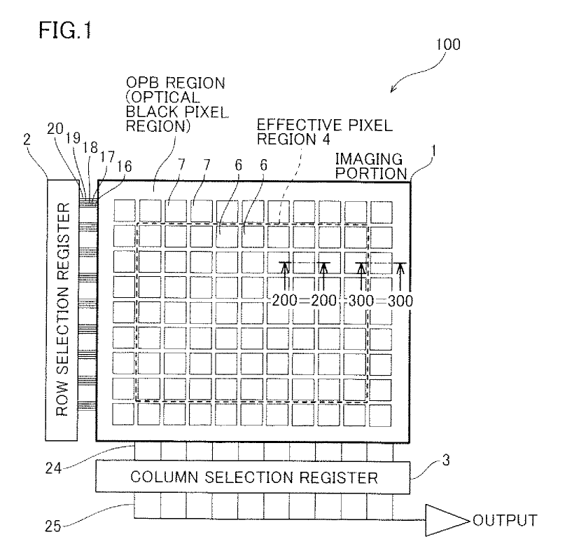

A first embodiment of the present invention is applied to an active CMOS image sensor 100, which is an exemplary image sensor. As shown in FIG. 1, the CMOS image sensor 100 includes an imaging portion 1, a row selection register 2 and a column selection register 3.

The imaging portion 1 includes an effective pixel region 4 and an OPB region (optical black pixel region) 5 provided to surround the effective pixel region 4. The effective pixel region 4 is provided with a plurality of effective pixels 6 arranged in the form of a matrix (in rows and columns). The OPB region 5 is provided with a plurality of OPB pixels 7 also arranged in the form of a matrix.

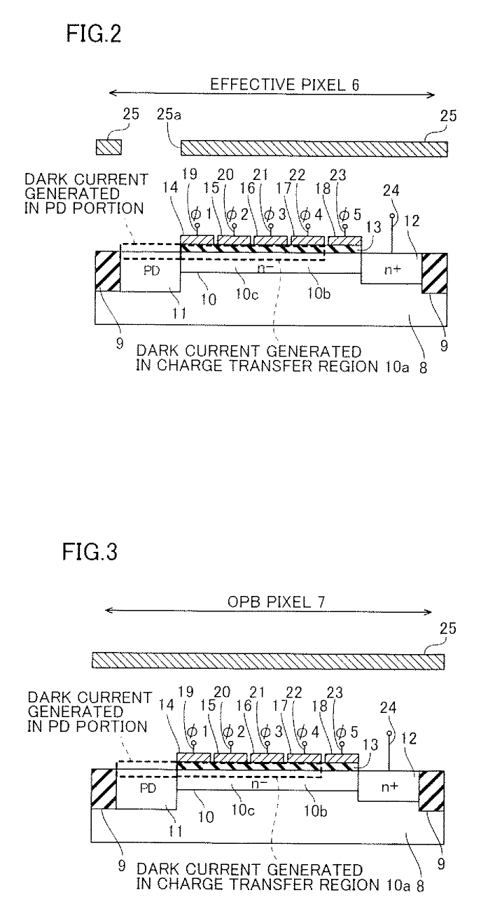

In the sectional structure of each effective pixel 6 arranged on the effective pixel region 4 of the imaging portion 1, an element isolation region 9 for isolating the effective pixel 6 is formed on the surface of a p-type silicon substrate 8, as shown in FIG. 2. On the surface of the p-type silicon substrate 8 of each effective pixel 6 surrounded by the element isolation region 9, a photodiode portion (PD portion) 11 and a floating diffusion region (FD region) 12 consisting of an n⁺-type impurity region are formed at a prescribed interval to hold a transfer channel 10 consisting of an n⁻-type impurity region therebetween. The PD portion 11 is an example of the “charge forming portion” in the present invention.

The PD portion 11 has a function of forming electrons (charges) in response to the quantity of incident light and storing the formed electrons. The PD portion 11 is formed to be adjacent to the element isolation region 9 as well as to the transfer channel 10.

The FD region 12 has a function of holding a charge signal resulting from transferred electrons and converting the charge signal to a voltage. The FD region 12 is also formed to be adjacent to the element isolation region 9 as well as to the transfer channel 10.

A gate insulating film 13 is formed on the surface of the transfer channel 10. On prescribed regions of the surface of the gate insulating film 13, a transfer gate electrode 14, a multiplier gate electrode 15, another transfer gate electrode 16, a storage gate electrode 17 and a read gate electrode 18 are formed in this order from the side of the PD portion 11 toward the side of the FD region 12 at prescribed intervals. A region of the transfer channel 10 located under the transfer gate electrode 14, the multiplier gate electrode 15, the transfer gate electrode 16 and the storage gate electrode 17 is a charge transfer region 10a. A region of the transfer channel 10 located under the storage gate electrode 17 is an electron storage portion 10b. A region of the transfer channel 10 located under the multiplier gate electrode 15 is an electron multiplying portion (charge increasing region) 10c.

Wires 19, 20, 21, 22 and 23 supplying clock signals Φ1, Φ2, Φ3, Φ4 and Φ5 for voltage control are electrically connected to the transfer gate electrode 14, the multiplier gate electrode 15, the transfer gate electrode 16, the storage gate electrode 17 and the read gate electrode 18 respectively. The wires 19, 20, 21, 22 and 23 are formed every row of the effective pixels 6 arranged in the form of a matrix, and electrically connected to transfer gate electrodes 14, multiplier gate electrodes 15, transfer gate electrodes 16, storage gate electrodes 17 and read gate electrodes 18 of a plurality of effective pixels 6 of each row respectively. A signal line 24 for extracting signals is electrically connected to the FD region 12.

A shielding metal member 25 made of a metal such as Al (aluminum) for shielding the p-type silicon substrate 8 from external light is formed above the p-type silicon substrate 8. An opening 25a is formed in a portion of the shielding metal member 25 located above the PD portion 11, so that the external light is applied to the PD portion 11.

In the sectional structure of each OPB pixel 7 provided on the OPB region 5, the shielding metal member 25 provided above the p-type silicon substrate 8 is so formed as to entirely cover a portion above the p-type silicon substrate 8, as shown in FIG. 3. The remaining structure of the OPB pixel 7 is similar to that of the effective pixel 6.

Dark current increased in proportion to time even in a state not exposed to the external light is generated in both of the PD portion 11 and the region of the transfer channel 10 located under the transfer gate electrode 14, the multiplier gate electrode 15, the transfer gate electrode 16 and the storage gate electrode 17.

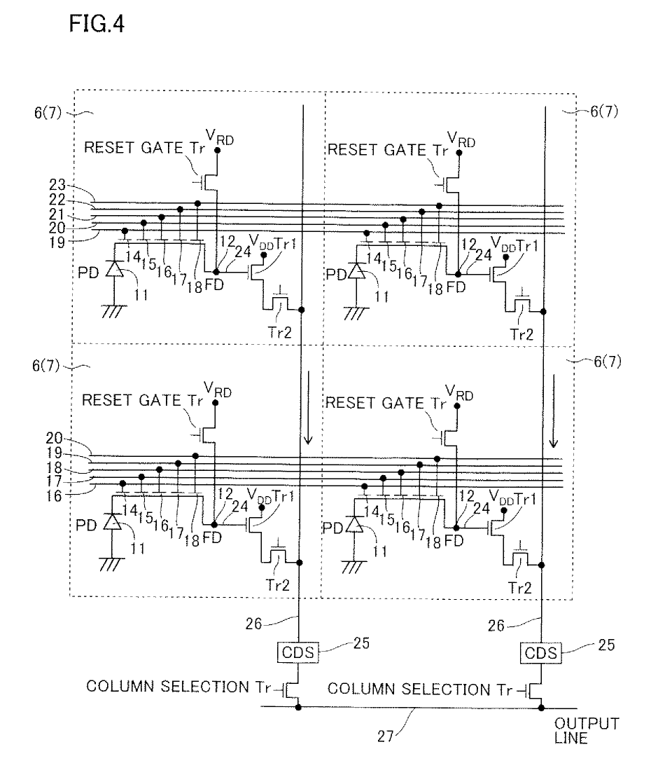

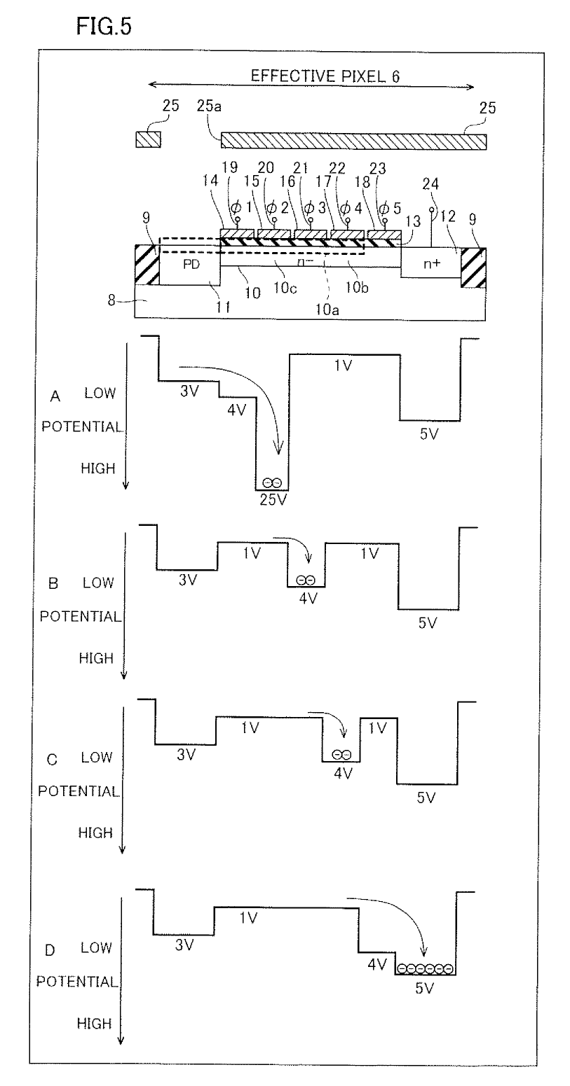

Each of the effective pixel 6 and the OPB pixel 7 is provided with a reset gate transistor Tr, an amplifier transistor Tr1 and a pixel selection transistor Tr2, as shown in FIG. 4.

A reset signal is supplied to the gate of the reset gate transistor Tr, while a rest voltage V_{RD} (about 5 V) is connected to the drain thereof. The source of the reset gate transistor Tr is connected to the FD region 12. The reset gate transistor Tr has a function of resetting the signal line 24 to the rest voltage V_{RD} (about 5 V) after reading the charge signal stored in the FD region 12 and holding the FD region 12 in an electrically floating state in reading.

The gate of the amplifier transistor Tr1 is connected to the signal line 24. A power supply voltage V_{DD} is connected to the drain of the amplifier transistor Tr1. The drain of the pixel selection transistor Tr2 is connected to the source of the amplifier transistor Tr1.

An output line 26 is connected to the source of the pixel selection transistor Tr2. An end of a correlated double sampling (CDS) circuit 25 is connected to the output line 26. Another end of the correlated double sampling circuit 25 is connected to the drain of a column selection transistor. The source of the column selection transistor is connected to another output line 27.

A charge signal reading operation of the CMOS image sensor 100 according to the first embodiment is described with reference to FIG. 4.

First, the reset gate transistor Tr of each of the effective pixels 6 and the OPB pixels 7 of a prescribed row is brought into an ON-state, thereby resetting the potential of the FD region 12 (signal line 24). Thereafter the pixel selection transistor Tr2 of each of the effective pixels 6 and the OPB pixels 7 of the prescribed row is brought into an ON-state, thereby reading a signal of a reset level on the correlated double sampling circuit 25.

Then, a high-level signal is supplied to the wire 23 for each of the effective pixels 6 and the OPB pixels 7 of the prescribed row, thereby bringing the read gate electrode 18 of each pixel of one row of the imaging portion 1 into an ON-state. Thus, electrons formed in the PD portion 11 of each pixel of one row are read on the FD region 12 (signal line 24).

From this state, the pixel selection transistor Tr2 of each of the effective pixels 6 and the OPB pixels 7 of the prescribed row in which the signal of the reset level has been read on the correlated double sampling circuit 25 is brought into an ON-state. Thus, a signal (charge signal) of the PD portion 11 amplified by the amplifier transistor Tr1 is read on the correlated double sampling circuit 25 through the pixel selection transistor Tr2.

The correlated sampling circuit 25 samples both of the signal of the reset level and the signal of the PD portion 11 and performs subtraction, thereby outputting a signal from which reset noise is removed. Thereafter column transistors are successively brought into ON-states, thereby outputting signals every effective pixel 6 and every OPB pixel 7. The CMOS image sensor 100 according to the first embodiment performs the reading operation by repeating the aforementioned operation every row.

An operation of transferring dark current (charge signal) in the CMOS image sensor 100 according to the first embodiment of the present invention is described with reference to FIGS. 4 and 5.

Before performing the transfer operation (before starting), the surface of the effective pixel region 4 of the imaging portion 1 is shielded from light with a mechanical shielding shutter (not shown), thereby producing a dark state. Then, the reset gate transistor Tr (see FIG. 4) is brought into an ON-state, thereby resetting the potential of the FD region 12 (signal line 24).

Then, the CMOS image sensor 100 is put on standby for a prescribed time, in order to acquire an output value of the dark current (charge signal) generated in both of the PD portion 11 and the charge transfer region 10a of the transfer channel 10. At this time, the standby time may be extended in order to acquire the small dark current in a larger quantity.

After a lapse of the prescribed time, the transfer gate electrode 14 is brought into an ON-state in a period A shown in FIG. 5, thereby controlling a portion of the transfer channel 10 located under the transfer gate electrode 14 to a potential of about 4 V. At this time, the PD portion 11 is controlled to a potential of about 3 V, whereby the dark current (charge signal) generated in the PD portion 11 is transferred from the PD portion 11 to the portion of the transfer channel 10 located under the transfer gate electrode 14. At this time, the dark current (charge signal) generated in the portion located under the transfer gate electrode 14 and the dark current (charge signal) transferred from the PD portion 11 are added up.

Thereafter the multiplier gate electrode 15 is brought into an ON-state, whereby the portion of the transfer channel 10 located under the multiplier gate electrode 15 is controlled to a potential of about 25 V. At this time, the portion of the transfer channel 10 located under the transfer gate electrode 14 is controlled to the potential of about 4 V, whereby the dark current (charge signal) transferred to the portion of the transfer channel 10 located under the transfer gate electrode 14 is transferred to the portion of the transfer channel 10 located under the multiplier gate electrode 15. At this time, the dark current (charge signal) generated in the portion of the transfer channel 10 located under the multiplier gate electrode 15 and the dark current (charge signal) transferred from the transfer gate electrode 14 are added up. Thereafter the transfer gate electrode 14 is brought into an OFF-state, whereby the portion of the transfer channel 10 located under the transfer gate electrode 14 is controlled to a potential of about 1 V.

Then, the transfer gate electrode 16 is brought into an ON-state and the multiplier gate electrode 15 is brought into an OFF-state in a period B shown in FIG. 5. Thus, a portion of the transfer channel 10 located under the transfer gate electrode 16 is controlled to a potential of about 4 V, and the portion of the transfer channel 10 located under the multiplier gate electrode 15 is controlled to a potential of about 1 V.

Thus, the dark current (charge signal) stored in the portion of the transfer channel 10 located under the multiplier gate electrode 15 is transferred to the portion of the transfer channel 10 located under the transfer gate electrode 16 controlled to the potential (about 4 V) higher than the potential (about 1 V) of the portion of the transfer channel 10 located under the multiplier gate electrode 15. At this time, the dark current (charge signal) generated in the portion located under the transfer gate electrode 16 and the dark current (charge signal) transferred from the multiplier gate electrode 15 are added up.

Then, the storage gate electrode 17 is brought into an ON-state and the transfer gate electrode 16 is brought into an OFF-state in a period C shown in FIG. 5. Thus, the portion of the transfer channel 10 located under the storage gate electrode 17 is controlled to a potential of about 4 V, and the portion of the transfer channel 10 located under the transfer gate electrode 16 is controlled to a potential of about 1 V.

Thus, the dark current (charge signal) transferred to the portion of the transfer channel 10 located under the transfer gate electrode 16 is transferred to the portion of the transfer channel 10 located under the storage gate electrode 17 controlled to the potential (about 4 V) higher than the potential (about 1 V) of the portion of the transfer channel 10 located under the transfer gate electrode 16. At this time, the dark current (charge signal) generated in the portion of the transfer channel 10 located under the storage gate electrode 17 and the dark current (charge signal) transferred from the transfer gate electrode 16 are added up. Thus, the dark current (charge signal) transferred from the PD portion 11 is temporarily stored in the portion (electron storage portion 10b) of the transfer channel 10 located under the storage gate electrode 17.

In order to read the added-up dark current (charge signal), the read gate electrode 18 is brought into an ON-state while electrons of the dark current (charge signal) are temporarily stored in the portion (electron storage portion 10b) of the transfer channel 10 located under the storage gate electrode 17. Then, the storage gate electrode 17 is brought into an OFF-state. Thus, the portion of the transfer channel 10 located under the read gate electrode 18 is controlled to a potential of about 4 V, while the portion of the transfer channel 10 located under the storage gate electrode 17 is controlled to a potential of about 1 V.

Thus, the electrons stored in the portion (electron storage portion 10b) of the transfer channel 10 located under the storage gate electrode 17 are transferred to the FD region 12 controlled to a potential (about 5 V) higher than the potential (about 1 V) of the portion of the transfer channel 10 located under the storage gate electrode 17 through the portion of the transfer channel 10 located under the read gate electrode 18 controlled to the potential of about 4 V.

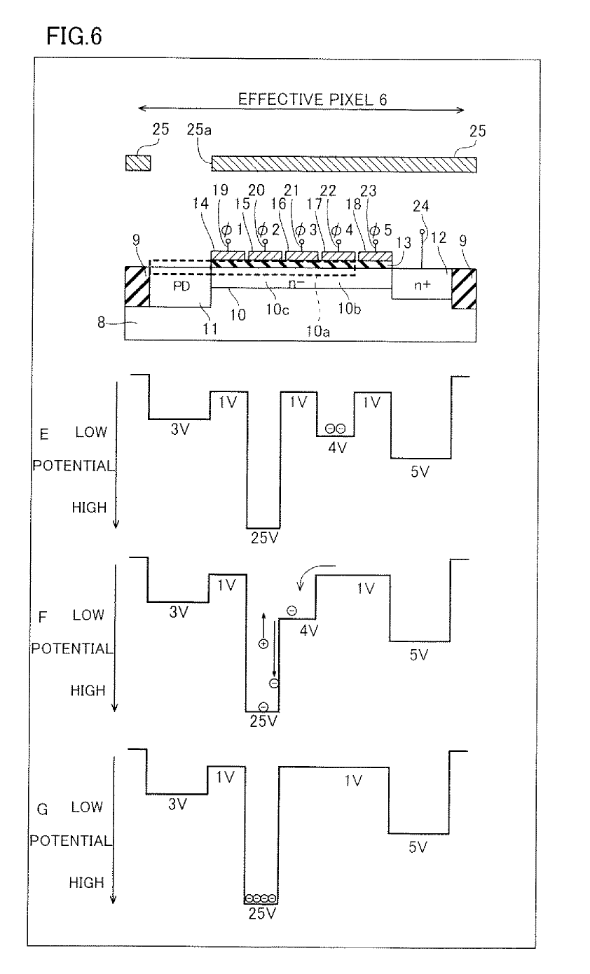

An operation of multiplying dark current (charge signal) in the CMOS image sensor 100 according to the first embodiment of the present invention is described with reference to FIGS. 5 and 6.

In the operation of multiplying the dark current (charge signal), the multiplier gate electrode 15 is brought into an ON-state while the portion (electron storage portion 10b) of the transfer channel 10 located under the storage gate electrode 17 stores the dark current (charge signal) in a period E shown in FIG. 6 after the transfer operation in the period C shown in FIG. 5. Thus, the portion (electron multiplying portion 10c) of the transfer channel 10 located under the multiplier gate electrode 15 is controlled to a high potential of about 25 V.

Then, the transfer gate electrode 16 is brought into an ON-state and the storage gate electrode 17 is brought into an OFF-state in a period F shown in FIG. 6. Thus, the portion of the transfer channel 10 located under the transfer gate electrode 16 is controlled to a potential of about 4 V, while the portion of the transfer channel 10 located under the storage gate electrode 17 is controlled to a potential of about 1 V. The dark current (charge signal) stored in the portion of the transfer channel 10 located under the storage gate electrode 17 is transferred to the portion of the transfer channel 10 located under the transfer gate electrode 16 controlled to the potential (about 4 V) higher than the potential (about 1 V) of the portion of the transfer channel 10 located under the storage gate electrode 17.

The dark current (charge signal) transferred to the portion of the transfer channel 10 located under the transfer gate electrode 16 is transferred to the portion of the transfer channel 10 located under the multiplier gate electrode 15 controlled to the potential (about 25 V) higher than the potential (about 4 V) of the portion of the transfer channel 10 located under the transfer gate electrode 16. The dark current (charge signal) transferred to the portion (electron multiplying portion 10c) of the transfer channel 10 located under the multiplier gate electrode 15 gains energy from a high electric field when moving through the boundary between the portions of the transfer channel 10 located under the multiplier gate electrode 15 and the transfer gate electrode 16 respectively. Electrons of the dark current (charge signal) having high energy collide with silicon atoms to form electrons and holes. Thereafter electrons formed by impact ionization are stored in the portion (electron multiplying portion 10c) of the transfer channel 10 located under the multiplier gate electrode 15 due to the electric field.

The transfer gate electrode 16 is brought into an OFF-state in a period G shown in FIG. 6, whereby the portion of the transfer channel 10 located under the transfer gate electrode 16 is controlled to a potential of about 1 V.

Then, the transfer operation for the dark current (charge signal) is performed in the periods B and C shown in FIG. 5, whereby the electrons stored in the portion (electron multiplying portion 10c) of the transfer channel 10 located under the multiplier gate electrode 15 are transferred to the portion (electron storage portion 10b) of the transfer channel 10 located under the storage gate electrode 17. Thereafter the aforementioned multiplying operation in the periods E to G and the transfer operation in the periods B and C are repetitively performed a plurality of times, thereby multiplying the electrons of the dark current (charge signal) transferred from the PD portion 11.

After the multiplying operation for the dark current (charge signal) is terminated in each of the effective pixels 6 and the OPB pixels 7, the dark current (charge signal) is stored in the portion (electron multiplying portion 10c) of the transfer channel 10 located under the multiplier gate electrode 15. Thereafter the electrons of the dark current (charge signal) are read on the FD region 12 every row of the effective pixels 6 and the OPB pixels 7 arranged in the form of matrices.

According to the first embodiment, as hereinabove described, the dark current is multiplied (increased) in both of the PD portion 11 and the charge transfer region 10a of the transfer channel 10 while the mechanical shielding shutter (not shown) shields the surfaces of the effective pixel region 4 and the OPB region 5 of the imaging portion 1 from light. A multiplication factor (increasing ratio) M, described later, for the dark current (charge signal) is calculated on the basis of output values resulting from the multiplied (increased) dark current (charge signal).

A method of calculating the multiplication factor M per multiplication frequency for the dark current (charge signal) based on output values resulting from the dark current (charge signal) multiplied in each of the effective pixel region 4 and the OPB region 5 of the imaging portion 1 is now described.

Output values Qₖ, Qₘ and Qₙ in cases of multiplying the dark current (charge signal) with multiplication frequencies k, m and n respectively can be expressed as follows respectively:

Qₖ=a+d×M^{k} (1)

Qₘ =a+d×M^{m} (2)

Qₙ=a+d×Mⁿ (3)

a represents an offset value (black level) of each of the effective pixels 6 and the OPB pixels 7, d represents the dark current (charge signal) not yet multiplied, and M represents the multiplication factor (increasing ratio) per multiplication frequency for the multiplied dark current (charge signal). k represents the maximum frequency allowing detection of the output value of the multiplied dark current (charge signal), m represents the minimum frequency allowing detection of the output value of the multiplied dark current (charge signal), and n represents the average of the maximum frequency k and the minimum frequency m. The maximum frequency k is an example of the “second frequency” in the present invention, and the maximum frequency k is an example of the “first frequency” in the present invention. The average frequency n is an example of the “third frequency” in the present invention.

Then, the above equations (1) to (3) are transformed into the following equation (4):

(Qₘ−Qₖ)/(Qₙ−Qₖ)=(M^{m}−M^{k})/(Mⁿ−M^{k}) (4)

The average frequency n of the maximum frequency k and the minimum frequency m can be expressed as follows:

n=(m+k)/2 (5)

The above equation (5) is substituted for the above equation (4), whereby the multiplication factor (increasing ratio) M per multiplication frequency for the multiplied dark current (charge signal) can be expressed in the following equation (6). If the average frequency n obtained from the maximum frequency k and the minimum frequency m is not an integer, a substantially average frequency of the maximum frequency k and the minimum frequency m may be calculated by recalculating the average frequency n as an integer.

M=((Qₘ−Qₙ)/(Qₙ−Qₖ))^{(2/(m-k))} (6)

Qₖ represents an output value with the multiplication frequency k, Qₘ represents an output value with the multiplication frequency m, and Q represents an output value with the multiplication frequency n.

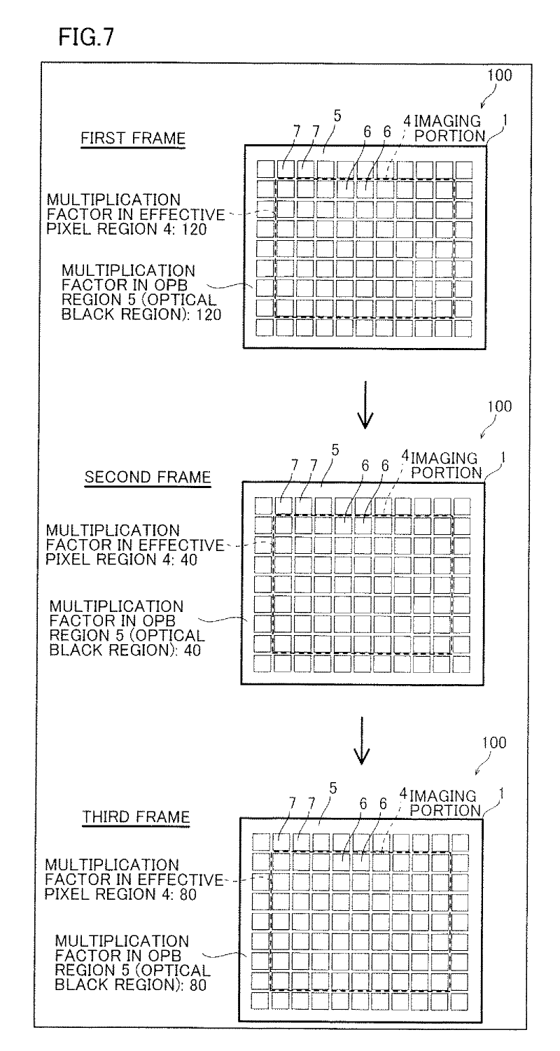

According to the first embodiment, the CMOS image sensor 100 is so formed as to calculate the multiplication factor M on the basis of output values obtained by multiplying the dark current (charge signal) generated in both of the PD portion 11 and the charge transfer region 10a of the transfer channel 10 with three types of different multiplication frequencies in a prescribed pixel among those provided on the effective pixel region 4 or the OPB region 5 of the imaging portion 1, as shown in FIG. 7.

More specifically, the dark current (charge signal) of the prescribed pixel among those in the effective pixel region 4 or the OPB region 5 is multiplied with a multiplication frequency 120 (k=120) and the output value Qₖ is acquired in a first frame. In a second frame, the dark current (charge signal) of the prescribed pixel is multiplied with a multiplication frequency 40 (m=40) and the output value Qₘ is acquired. In a third frame, the dark current (charge signal) of the prescribed pixel is multiplied with a multiplication frequency 80 (n=80) and the output value Qₙ is acquired.

The acquired output values Qₖ, Qₘ and Qₙ are substituted for the above equation (6), thereby calculating the multiplication factor M per multiplication frequency for the dark current (charge signal) of the prescribed pixel. In other words, what percentage of the dark current (charge signal) is multiplied per multiplication frequency for the dark current (charge signal) can be calculated.

Further, an output value Q in a case of multiplying the dark current (charge signal) with an arbitrary multiplication frequency can also be calculated through the calculated multiplication factor M. When the multiplication factor M is 1.03 (increased by 3%) and the dark current (charge signal) is multiplied with a multiplication frequency 50, for example, the output value Q is calculated as follows:

Q=1.03⁵⁰

The CMOS image sensor 100 according to the first embodiment of the present invention can attain the following effects:

(1) The CMOS image sensor 100 multiplies the dark current (charge signal) generated in both of the PD portion 11 and the charge transfer region 10a of the transfer channel 10 in the portion (electron multiplying portion 10c) of the transfer channel 10 located under the multiplier gate electrode 15. Then, the CMOS image sensor 100 calculates the multiplication factor M per multiplication frequency for the multiplied dark current (charge signal) on the basis of the output values Qₖ, Qₘ and Qₙ resulting from the multiplied dark current (charge signal). Thus, the output value of the dark current (charge signal) multiplied with the arbitrary multiplication frequency is acquired, whereby the CMOS image sensor 100 can calculate the multiplication factor M for the dark current (charge signal) multiplied with the arbitrary multiplication frequency from the acquired output value.

(2) The CMOS image sensor 100 multiplies the dark current (charge signal) generated in both of the PD portion 11 and the charge transfer region 10a of the transfer channel 10 with the three types of different multiplication frequencies (the maximum frequency k, the minimum frequency m and the average frequency n). Then, the CMOS image sensor 100 calculates the multiplication factor M per multiplication frequency for the dark current (charge signal) on the basis of the output values Qₖ, Qₘ and Qₙ resulting from the multiplied dark current (charge signal). Thus, three types of multiplication factors M are calculated, whereby the CMOS image sensor 100 can calculate a correct multiplication factor M while removing a random component by averaging the calculated three types of multiplication factors M.

### Second Embodiment

A CMOS image sensor 100 according to a second embodiment of the present invention is now described with reference to FIG. 3. The CMOS image sensor 100 according to the second embodiment is so formed as to calculate a multiplication factor M on the basis of output values obtained by multiplying only dark current generated in each OPB pixel 7 provided on an OPB region 5, dissimilarly to the aforementioned first embodiment.

The CMOS image sensor 100 according to the second embodiment multiplies dark current generated in both of a PD portion 11 provided on each OPB pixel 7 of the OPB region 5 of an imaging portion 1 and a charge transfer region 10a of a transfer channel 10 with three types of different multiplication frequencies (k, m and n), as shown in FIG. 3. The CMOS image sensor 100 is so formed as to calculate a multiplication factor M per multiplication frequency for the dark current on the basis of output values of the multiplied dark current.

The remaining structure of the second embodiment is similar to that of the aforementioned first embodiment.

In a transfer operation for the dark current (charge signal) in the CMOS image sensor 100 according to the second embodiment, the OPB region 5 is shielded from light by a shielding metal member 25, and hence an operation of shielding the imaging portion 1 from light with a mechanical shielding shutter before the transfer operation (before starting) may be omitted, dissimilarly to the transfer operation in the aforementioned first embodiment.

The remaining transfer operation, a multiplying operation and a method of calculating the multiplication factor M in the second embodiment are similar to those in the aforementioned first embodiment.

The CMOS image sensor 100 according to the second embodiment of the present invention can attain the following effect:

(3) The CMOS image sensor 100 multiplies the dark current (charge signal) generated in both of the PD portion 11 provided on each OPB pixel 7 of the OPB region 5 and the charge transfer region 10a of the transfer channel 10. Then, the CMOS image sensor 100 calculates the multiplication factor M per multiplication frequency for the dark current (charge signal) on the basis of output values resulting from the multiplied dark current (charge signal). Thus, the multiplication factor M is calculated on the basis of the output values resulting from the dark current (charge signal) generated in the region shielded from light by the shielding metal member 25 provided above the surface of the OPB pixel 7 of the OPB region 5, whereby no mechanism such as a shielding shutter for producing a dark state may be separately provided. Consequently, increase in the number of components can be suppressed.

### Third Embodiment

A CMOS image sensor 100 according to a third embodiment of the present invention is now described with reference to FIGS. 1, 2, 5 and 6. The CMOS image sensor 100 according to the third embodiment multiplies both of dark current generated in a charge transfer region 10a of a transfer channel 10 located under a multiplier gate electrode 15, a transfer gate electrode 16 and a storage gate electrode 17 of each effective pixel 6 provided on an effective pixel region 4 and dark current generated in each OPB pixel 7 provided on an OPB region 5, dissimilarly to the aforementioned first embodiment. The CMOS image sensor 100 is so formed as to calculate a multiplication factor M on the basis of output values of multiplied dark current. In other words, the CMOS image sensor 100 is so formed as to multiply dark current (charge signal) other than dark current generated in a PD portion 11 of the effective pixel 6 and dark current generated in a portion of the transfer channel 10 located under a transfer gate electrode 14, for calculating the multiplication factor M on the basis of output values of the multiplied dark current (charge signal).

The remaining structure of the third embodiment is similar to that of the aforementioned first embodiment.

A transfer operation for the dark current (charge signal) in the CMOS image sensor 100 according to the third embodiment of the present invention is now described.

In the transfer operation for the dark current (charge signal) in the CMOS image sensor 100 according to the third embodiment of the present invention, a region of the effective pixel region 4 other than the effective pixel 6 is shielded from light by a shielding metal member 25. Therefore, an operation of shielding an imaging portion 1 from light with a mechanical shielding shutter before the transfer operation (before starting) may be omitted, dissimilarly to the transfer operation in the aforementioned first embodiment.

In the transfer operation for the dark current (charge signal) according to the third embodiment, the transfer gate electrode 14 of the effective pixel 6 of the effective pixel region 4 is regularly kept in an OFF-state. Thus, when the transfer operation for the dark current (charge signal) is performed, the dark current (charge signal) generated in the PD portion 11 of the effective pixel 6 is not transferred from the side of the PD portion 11 toward the side of the transfer channel 10. Thereafter the CMOS image sensor 100 according to the third embodiment performs operations similar to those of the aforementioned first embodiment in the periods B to D shown in FIG. 5 and in the periods E to G shown in FIG. 6, thereby multiplying the dark current (charge signal).

The remaining transfer operation, a multiplying operation and a method of calculating the multiplication factor M in the third embodiment are similar to those in the aforementioned first embodiment.

The CMOS image sensor 100 according to the third embodiment of the present invention can attain the following effect:

(4) The CMOS image sensor 100 increases both of the dark current (charge signal) generated in the PD portion 11 provided on the OPB pixel 7 of the OPB region 5 as well as the charge transfer region 10a of the transfer channel 10 and the dark current (charge signal) generated in the portion of the transfer channel 10 located under the multiplier gate electrode 15, the transfer gate electrode 16 and the storage gate electrode 17 provided on the effective pixel 6 of the effective pixel region 4. The CMOS image sensor 100 calculates the multiplication factor M per multiplication frequency for the dark current (charge signal) on the basis of output values resulting from the increased dark current (charge signal). Thus, an output value of the dark current (charge signal) multiplied with an arbitrary multiplication frequency is acquired in the OPB pixel 7 of the OPB region 5, whereby the CMOS image sensor 100 can calculate the multiplication factor M for the dark current (charge signal) multiplied with the arbitrary multiplication frequency from the acquired output value.

### Fourth Embodiment

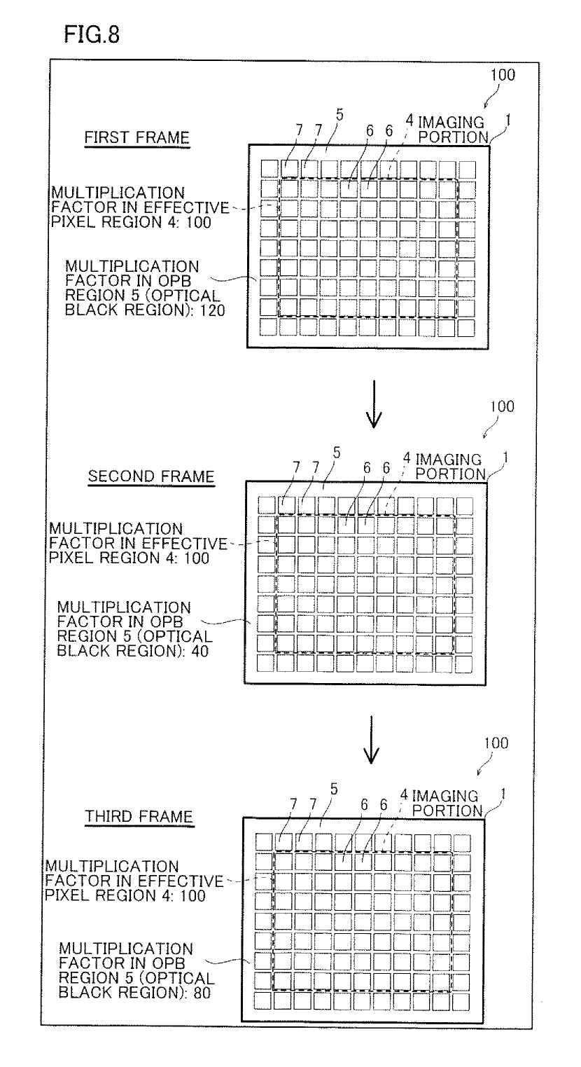

A CMOS image sensor 100 according to a fourth embodiment of the present invention is now described with reference to FIG. 8. In the CMOS image sensor 100 according to the fourth embodiment, multiplication frequencies for dark current (charge signal) of each effective pixel 6 provided on an effective pixel region 4 and that for dark current of each OPB pixel 7 provided on an OPB region 5 are different from each other, dissimilarly to the aforementioned first embodiment. The remaining structure of the fourth embodiment is similar to that of the aforementioned first embodiment.

The CMOS image sensor 100 according to the fourth embodiment of the present invention multiplies the dark current (charge signal) of the OPB pixel 7 of the OPB region 5 with a multiplication frequency 120 (k=120) and acquires an output value Qₖ in a first frame, as shown in FIG. 8. In a second frame, the CMOS image sensor 100 multiplies the dark current (charge signal) of the OPB pixel 7 of the OPB region 5 with a multiplication frequency 40 (m=40) and acquires an output value Qₘ. In a third frame, the CMOS image sensor 100 multiplies the dark current (charge signal) of the OPB pixel 7 of the OPB region 5 with a multiplication frequency 80 (n=80) and acquires an output value Qₙ.

On the other hand, the CMOS image sensor 100 multiplies the dark current (charge signal) of each effective pixel 6 of the effective pixel region 4 with a multiplication frequency 100 from the first frame to the third frame. The multiplication frequency (100) for the dark current (charge signal) of the effective pixel 6 of the effective pixel region 4 is merely an example, and can be varied with darkness (brightness) of a subject.

The CMOS image sensor 100 calculates a multiplication factor M for the dark current (charge signal) by substituting three types of output values resulting from the dark current (charge signal) multiplied in the OPB pixel 7 of the OPB region 5 in the first to third frames for the above equation (6). As hereinabove described, the multiplication frequencies for the dark current (charge signal) of the OPB pixel 7 of the OPB region 5 and that for the dark current (charge signal) of the effective pixel 6 of the effective pixel region 4 are different from each other. Thus, the CMOS image sensor 100 can image a subject in the effective pixel region 4 while calculating the multiplication factor M for the dark current (charge signal) in the OPB region 5. Consequently, the CMOS image sensor 100 can reflect transition (change) of the multiplication factor M with respect to the temperature, deterioration etc. on control of an exposure time in imaging or digital signal processing in real time.

The remaining transfer operation, a multiplying operation and a method of calculating the multiplication factor M in the fourth embodiment are similar to those in the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the CMOS image sensor multiplies the dark current (charge signal) with the three types of frequencies in each of the aforementioned first to fourth embodiments, the present invention is not restricted to this, but the dark current (charge signal) may alternatively be multiplied with frequencies other than the three types of frequencies.

While the CMOS image sensor multiplies the dark current (charge signal) with the three types of frequencies, i.e., 40, 80 and 120 in each of the aforementioned first to fourth embodiments, the present invention is not restricted to this, but the number of the types of the frequencies may be other than the above so far as output values of the multiplied dark current (charge signal) are detectable.

While the CMOS image sensor acquires the output values of the dark current (charge signal) multiplied in the prescribed pixel from the first frame to the third frame as an exemplary pixel from which output values of the multiplied dark current (charge signal) are acquired in each of the aforementioned first to fourth embodiments, the present invention is not restricted to this, but the CMOS image sensor may alternatively acquire output values of the multiplied dark current in a plurality of pixels in the same frame.

While the CMOS image sensor acquires the output values of the multiplied dark current (charge signal) in the prescribed pixel in the effective pixel region 4 or the OPB region 5 from the first frame to the third frame in each of the aforementioned first to fourth embodiments, the present invention is not restricted to this. For example, the CMOS image sensor first acquires respective output values from the first frame to the third frame and calculates a multiplication factor M1 of a first set. Then, the CMOS image sensor acquires respective output values from a fourth frame to a sixth frame and calculates a multiplication factor M2 of a second set. Thus, the CMOS image sensor repeats acquisition of respective output values by a plurality of sets (a plurality of times). Then, the CMOS image sensor may calculate the average of the multiplication factors M1, M2, . . . calculated in the respective sets as a final multiplication factor M.

While the CMOS image sensor acquires the output values of the multiplied dark current (charge signal) in the pixel in the first frame to the third frame as an exemplary pixel from which the output values of the multiplied dark current (charge signal) are acquired in each of the aforementioned first to fourth embodiments, the present invention is not restricted to this, but the CMOS image sensor may alternatively calculate the multiplication factor M for the dark current (charge signal) by a method of a pipeline system (system calculating a factor while overlapping partial data). For example, the CMOS image sensor first acquires output values from a first frame to a third frame and calculates a multiplication factor M1. Then, the CMOS image sensor acquires output values from the second frame to a fourth frame and calculates a multiplication factor M2. Further, the CMOS image sensor acquires output values from the third frame to a fifth frame and calculates a multiplication factor M3. Thus, the CMOS image sensor may calculate the multiplication factors while overlapping the output values (frames) to be acquired. More specifically, the CMOS image sensor first calculates the multiplication factor M1 from output values obtained by multiplying dark current (charge signal) with multiplication frequencies 40 (first frame), 80 (second frame) and 120 (third frame). Then, the CMOS image sensor calculates the multiplication factor M2 from output values obtained by multiplying the dark current (charge signal) with multiplication frequencies 80 (second frame), 120 (third frame) and 40 (fourth frame). Further, the CMOS image sensor calculates the multiplication factor M3 from output values obtained by multiplying the dark current with multiplication frequencies 120 (third frame), 40 (fourth frame) and 80 (fifth frame). Then, the CMOS image sensor may calculate the average of the calculated multiplication factors M1, M2 and M3.

What is claimed is:

1. An image sensor comprising:
a charge forming portion forming charges by photoelectric conversion; and
a charge transfer region including a charge increasing region for increasing the amount of charges,
for increasing dark current generated in at least part of said charge forming portion and said charge transfer region in said charge increasing region and calculating an increasing ratio for said charges on the basis of an output value resulting from a charge signal of increased said dark current.

2. The image sensor according to claim 1, so formed as to increase said dark current with at least three types of frequencies for calculating said increasing ratio for said charges on the basis of respective output values resulting from said charge signal of said increased dark current.

3. The image sensor according to claim 2, increasing said dark current with three types of frequencies including a first frequency with which an output value resulting from said charge signal of said increased dark current is larger than a minimum detectable value, a second frequency, larger than said first frequency, with which an output value resulting from said charge signal of said increased dark current is smaller than a maximum detectable value and a third frequency substantially corresponding to the average of said first frequency and said second frequency.

4. The image sensor according to claim 2, so formed as to calculate said increasing ratio for said charges as an increasing ratio per increasing frequency for said dark current.

5. The image sensor according to claim 4, so formed as to acquire an increasing ratio for said charges with an arbitrary increasing frequency on the basis of calculated said increasing ratio per increasing frequency for said dark current.

6. The image sensor according to claim 2, so formed as to acquire said increasing ratio for said charges by increasing said dark current with at least three types of frequencies, calculating at least three increasing ratios on the basis of respective output values resulting from said charge signal of said increased dark current and thereafter averaging said three increasing ratios.

7. The image sensor according to claim 1, increasing both of dark current generated in said charge forming portion and dark current generated in said charge transfer region.

8. The image sensor according to claim 1, further comprising:
an effective pixel region, and
an optical black pixel region provided to surround said effective pixel region, wherein
each of a pixel of said effective pixel region and a pixel of said optical black pixel region includes said charge forming portion, a voltage conversion portion and said charge transfer region having said charge increasing region,
for increasing dark current generated in at least part of said charge forming portion and said charge transfer region provided on said pixel of at least either said optical black pixel region or said effective pixel region.

9. The image sensor according to claim 8, increasing dark current generated in at least part of said charge forming portion and said charge transfer region provided on said pixel of at least said optical black pixel region in said optical black pixel region and said effective pixel region.

10. The image sensor according to claim 9, increasing dark current generated in at least part of said charge forming portion and said charge transfer region provided not on said pixel of said effective pixel region but on said pixel of said optical black pixel region.

11. The image sensor according to claim 8, increasing dark current generated in at least part of said charge forming portions and said charge transfer regions provided on said pixels of both of said optical black pixel region and said effective pixel region.

12. The image sensor according to claim 8, increasing dark current generated in at least part of said charge forming portion and said charge transfer region provided on said pixel of at least said effective pixel region in said optical black pixel region and said effective pixel region while increasing said dark current in a state shielding said effective pixel region from light.

13. The image sensor according to claim 8, increasing said dark current with different frequencies in said optical black pixel region and said effective pixel region.

14. The image sensor according to claim 8, increasing dark current generated in one prescribed pixel of at least either said optical black pixel region or said effective pixel region.

15. The image sensor according to claim 1, wherein
said charge increasing region is so formed as to increase the amount of charges of said dark current by impact ionization.

16. A CMOS image sensor comprising:
a charge forming portion forming charges by photoelectric conversion; and
a charge transfer region including a charge increasing region for increasing the amount of charges, wherein
said charge increasing region is provided every pixel,
for increasing dark current generated in at least part of said charge forming portion and said charge transfer region in said charge increasing region and calculating an increasing ratio for said charges on the basis of an output value resulting from a charge signal of increased said dark current.

17. The CMOS image sensor according to claim 16, so formed as to increase said dark current with at least three types of frequencies for calculating said increasing ratio for said charges on the basis of respective output values resulting from said charge signal of said increased dark current.

18. The CMOS image sensor according to claim 17, increasing said dark current with three types of frequencies including a first frequency with which an output value resulting from said charge signal of said increased dark current is larger than a minimum detectable value, a second frequency, larger than said first frequency, with which an output value resulting from said charge signal of said increased dark current is smaller than a maximum detectable value and a third frequency substantially corresponding to the average of said first frequency and said second frequency.

19. The CMOS image sensor according to claim 16, increasing both of dark current generated in said charge forming portion and dark current generated in said charge transfer region.

20. The CMOS image sensor according to claim 16, further comprising:
an effective pixel region, and
an optical black pixel region provided to surround said effective pixel region, wherein
each of a pixel of said effective pixel region and a pixel of said optical black pixel region includes said charge forming portion, a voltage conversion portion and said charge transfer region having said charge increasing region,
for increasing dark current generated in at least part of said charge forming portion and said charge transfer region provided on said pixel of at least either said optical black pixel region or said effective pixel region.
